(19) United States
(12) Patent Application Publication
(10) Pub. No.: US 2026/0268829 A1
(43) Pub. Date: Sep. 10, 2026

(54) SHIFT REGISTER UNIT, AND DISPLAY PANEL AND DRIVING METHOD THEREFOR

(71) Applicants: Beijing BOE Display Technology Co., Ltd., Beijing (CN); BOE Technology Group Co., Ltd., Beijing (CN)

(72) Inventor: Tao YANG, Beijing (CN)

(73) Assignees: Beijing BOE Display Technology Co., Ltd., Beijing (CN); BOE Technology Group Co., Ltd., Beijing (CN)

(21) Appl. No.: 18/993,578

(22) PCT Filed: Jan. 19, 2023
(86) PCT No.: PCT/CN2023/073233

§ 371 Date: Jan. 13, 2025

(30) Foreign Application Priority Data
Jan. 18, 2023 (WO) PCT/CN2023/072870

(51) Int. Cl. G09G 3/20; G11C 19/28

(52) U.S. Cl. CPC G09G 3/2096; G11C 19/28; G09G 2300/0408; G09G 2310/0267

(57) ABSTRACT

The shift register unit includes a pull-up module, a cascade control module and a gate control module, where the pull-up module is connected to an input end and a pull-up node, and is used for using the signal of the input end to pull up the pull-up node; the cascade control module is connected to a first clock signal end, the pull-up node and a cascade signal output end, and is used for transmitting, in response to a signal of the pull-up node, a signal of the first clock signal end to the cascade signal output end; and the gate control module is connected to the pull-up node, a second clock signal end and a gate signal output end, and is used for transmitting, in response to the signal of the pull-up node, a signal of the second clock signal end to the gate signal output end.

### CROSS-REFERENCE TO RELATED APPLICATIONS

The present application is a U.S. National Stage of International Application No. PCT/CN2023/073233, filed on Jan. 19, 2023, which claims priority to the PCT international patent application entitled “shift register unit, and display panel and driving method therefor” with application number PCT/CN2023/072870 filed on Jan. 18, 2023, both of which are incorporated herein by reference in their entireties for all purposes.

### TECHNICAL FIELD

The present disclosure relates to the field of display technology, and in particular to a shift register unit, a display panel and a driving method thereof.

### BACKGROUND

There is a great demand for medium and large-sized display products with integrated touch functions in the fields of education and office, but currently in-cell touch display panels are mainly concentrated in small and medium sizes. Due to the large panel size, the corresponding driving load is higher for medium and large sizes, and the driving capability for the circuit is required to be higher.

The existing touch products have the problem of displaying horizontal stripes during LHB (long-horizontal-blanking, intra-frame touch detection).

It should be noted that the information disclosed in the above background technology section is only used to enhance the understanding of the background of the present disclosure, and therefore may include information that does not constitute prior art known to those skilled in the art.

### SUMMARY

According to an aspect of the present disclosure, there is provided a shift register unit, including a pull-up module connected to an input terminal and a pull-up node, where the pull-up module is configured to pull up the pull-up node by a signal of the input terminal in response to the signal of the input terminal; a cascade control module connected to a first clock signal terminal, the pull-up node and a cascade signal output terminal, where the cascade control module is configured to transmit a signal of the first clock signal terminal to the cascade signal output terminal in response to a signal of the pull-up node; and a gate control module connected to the pull-up node, a second clock signal terminal and a gate signal output terminal, where the gate control module is configured to transmit a signal of the second clock signal terminal to the gate signal output terminal in response to the signal of the pull-up node.

According to a second aspect of the present disclosure, there is provided a touch display panel, including a gate driving circuit, where the gate driving circuit includes a plurality of shift register units according to any one of embodiments of the present disclosure, and the plurality of shift register units are cascaded.

According to a third aspect of the present disclosure, there is also provided a display panel driving method, for driving the touch display panel according to any one of embodiments of the present disclosure, where the method includes arranging a display phase and a touch phase adjacent to each other in time sequence; in the display phase, determining a target shift register unit, a cascade control module and a gate control module in the target shift register unit both have output a conducting level in the display phase, and a gate control module in a shift register unit of a next stage of the target shift register unit does not output a conducting level in the display phase; in the touch phase, controlling a cascade signal output terminal of the target shift register unit to output the conducting level by controlling the second clock signal terminal to output a non-conducting level to the target shift register unit, and controlling the first clock signal terminal to output the conducting level to the target shift register unit for at least part of time.

It should be understood that the above general description and the detailed description below are only exemplary and explanatory, and cannot limit the present disclosure.

### BRIEF DESCRIPTION OF THE DRAWINGS

The drawings herein are incorporated into the specification and constitute a part of the specification, showing embodiments consistent with the present disclosure, and together with the specification, are used to explain the principles of the present disclosure. Obviously, the drawings described below are only some embodiments of the present disclosure, and for those skilled in the art, other drawings can be obtained based on these drawings without creative work.

FIG. 1 is a schematic diagram of a structure of a shift register unit according to an embodiment of the present disclosure;

FIG. 2 is a schematic diagram of the cascade of the shift register units in FIG. 1;

FIG. 3 is a working timing diagram of the cascade structure shown in FIG. 2;

FIG. 4 is a timing diagram when a pull-up node is not compensated provided by an embodiment;

FIG. 5 is a schematic diagram of a structure of a shift register unit according to another embodiment of the present disclosure;

FIG. 6 is a circuit structure diagram of a shift register unit according to still another embodiment of the present disclosure;

FIG. 7 is a timing diagram of the circuit shown in FIG. 6;

FIG. 8 is another example timing diagram of the cascade structure shown in FIG. 2;

FIG. 9 is another example timing diagram of the cascade structure shown in FIG. 2;

FIG. 10 is another example timing diagram of the cascade structure shown in FIG. 2;

FIG. 11 is a schematic diagram of a structure of a shift register unit according to another embodiment of the present disclosure;

FIG. 12 is a schematic diagram of a circuit structure for implementing the shift register unit shown in FIG. 11 according to an embodiment of the present disclosure;

FIG. 13 is a schematic diagram of the cascade of the shift register unit shown in FIG. 11;

FIG. 14 is a timing diagram of the circuit shown in FIG. 13.

### DETAILED DESCRIPTION

Example embodiments will now be described more fully with reference to the accompanying drawings. However, example embodiments can be implemented in a variety of forms and should not be construed as limited to the embodiments set forth herein; rather, these embodiments are provided so that the present disclosure will be comprehensive and complete and the concepts of the example embodiments will be fully conveyed to those skilled in the art. The same reference numerals in the figures represent the same or similar structures, and their detailed description will be omitted. In addition, the drawings are only schematic illustrations of the present disclosure and are not necessarily drawn to scale.

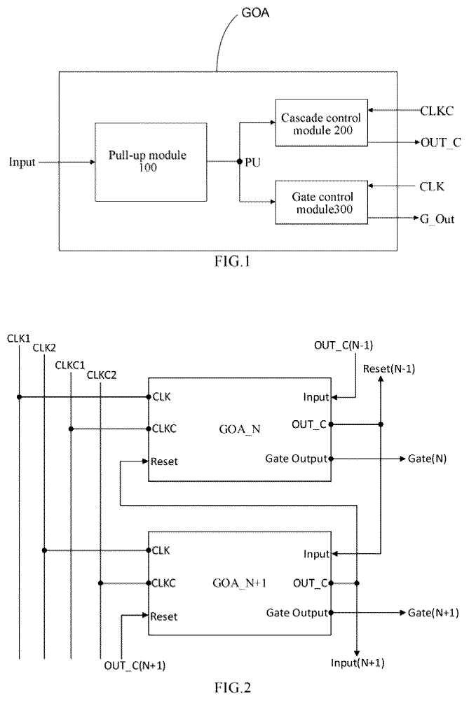

FIG. 1 is a schematic diagram of a structure of a shift register unit according to an embodiment of the present disclosure. As shown in FIG. 1, the shift register unit GOA may include a pull-up module 100, a cascade control module 200 and a gate control module 300. The pull-up module 100 is connected to the input terminal Input and the pull-up node PU. The pull-up module 100 may be configured to respond to the signal of the input terminal Input and use the signal of the input terminal Input to pull up the pull-up node PU. The cascade control module 200 is connected to the first clock signal terminal CLKC, the pull-up node PU and the cascade signal output terminal OUT_C. The cascade control module 200 may be configured to transmit the signal of the first clock signal terminal CLKC to the cascade signal output terminal OUT_C in response to the signal of the pull-up node PU. The gate control module 300 is connected to the pull-up node PU, the second clock signal terminal CLK and the gate signal output terminal G_Out. The gate control module 300 may be configured to transmit the signal of the second clock signal terminal CLK to the gate signal output terminal G_Out in response to the signal of the pull-up node PU.

The shift register unit GOA provided in the present disclosure controls the cascade control module 200 and the gate control module 300 independently using the signals of the two clock signal terminals. Thus, in the touch phase of the display panel, the first clock signal terminal CLKC connected to the cascade control module 200 can output a conducting level to perform voltage compensation to the gate control module 300 in the shift register unit GOA that has been charged before the touch phase but has not yet output a gate signal, so as to eliminate differences in the display brightness between different display and touch cycles caused by leakage in the touch phase. At the same time, the second clock signal terminal CLK connected to the gate control module 300 is controlled to output a non-conducting level, thereby avoiding the display horizontal stripe problem caused by repeated charging of pixel rows.

The shift register unit GOA of the present disclosure can be applied to an in-cell touch display panel. The touch display panel can include a gate driving circuit, and the gate driving circuit can include a plurality of cascaded shift register units GOA described in the present disclosure. In a frame of data, the touch display panel can alternately operate in the display phase and the LHB touch phase. For example, a frame of data can include at least two display phases and at least one LHB touch phase, and the LHB touch phase is between two adjacent display phases. In other words, the touch display panel can enter the LHB touch phase after a display phase, and then enter the display phase again after the LHB touch phase ends. When there are multiple display phases and multiple LHB touch phases, this is repeated. In the LHB touch phase, the touch display panel performs touch detection without pixel scanning. In the following part of the present disclosure, unless otherwise specified, the touch phase refers to the LHB touch phase, and the display horizontal stripe problem is solved by voltage compensation in the LHB touch phase.

The gate control module 300 in the shift register unit GOA is configured to output a gate driving signal to the pixel driving circuit of the display area, and the cascade control module 200 is configured to output a cascade signal. That is, the gate driving signal and the cascade signal are output by two different circuit modules. In this way, the cascade control module 200 and the gate control module 300 can be independently controlled in the touch phase.

The shift register units GOA of respective stages of the present disclosure can be cascaded through cascade signals. For example, FIG. 2 is a schematic diagram of the cascade of the shift register units in FIG. 1, in which the structure of two first clock signal terminals CLKC and two second clock signal terminals CLK is used as an example for explanation. As shown in FIG. 1 and FIG. 2, a shift register unit GOA may include a cascade control module 200 and a gate control module 300. The cascade signal output terminal OUT_C of the shift register unit GOA_N of the previous stage can be connected to the input terminal Input of the shift register unit GOA_N+1 of the next stage, and cascaded in sequence, so that the shift register unit GOA_N+1 of the next stage can be controlled to shift output by the cascade signal of the shift register unit GOA_N of the previous stage. At the same time, the cascade signal output terminal OUT_C of the shift register unit GOA_N+1 of the next stage can be connected to the reset signal terminal of the shift register unit GOA_N of the previous stage, so that the shift register unit GOA_N of the previous stage can be reset by the cascade signal of the shift register unit GOA_N+1 of the next stage.

The level output by a certain signal terminal being a conducting level described in the present disclosure can be understood as the level output by the signal terminal can conduct or turn on the circuit structure connected to the signal terminal or can pull up the voltage of the node connected to the signal terminal. Correspondingly, the level output by a certain signal terminal being a non-conducting level means that the level signal output by the signal terminal can turn off the circuit structure connected to the signal terminal or pull down the voltage of the node connected to the signal terminal.

In addition, the “pull-up” described in the present disclosure refers to pulling the potential at the corresponding circuit node to a high level to charge the node. It can be understood that “pull-up” can be achieved by directional movement of the charge, so it can be specifically achieved by electronic components with corresponding functions or their combination, and the present disclosure does not limit this.

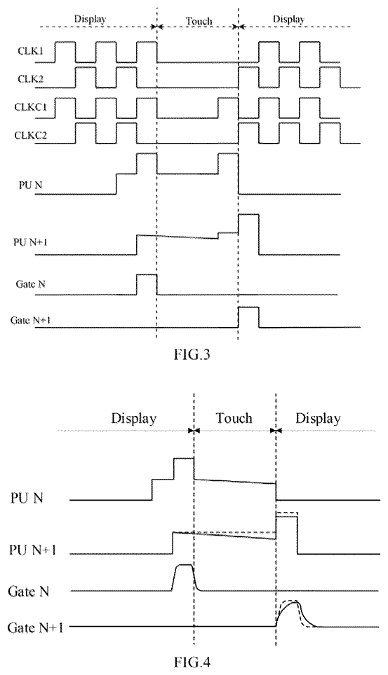

FIG. 3 is a working timing diagram of the cascade structure shown in FIG. 2, in which a high level is a conducting level, a low level is a non-conducting level, PU N represents a signal of a pull-up node PU in the shift register unit GOA corresponding to the Nth row of pixels, and PU N+1 represents a signal of a pull-up node PU in the shift register unit GOA corresponding to the (N+1)th row of pixels, and the figure takes the case where the touch control stage is entered when the display pixel row scanning ends at the Nth row as an example for illustrative explanation, at which time, the gate signal output terminal G_Out of the shift register unit GOA corresponding to the Nth row of pixels completes outputting the gate driving signal, and its pull-up node PU is in a high level state, waiting for reset. At the same time, the pull-up node PU of the shift register unit GOA corresponding to the (N+1)th row of pixels has just completed charging and is also in a high level state, waiting for the second clock signal terminal CLK to output a conducting level. Since the display pixel row scanning is not performed in the touch phase, the second clock signal terminal CLK continuously outputs non-conducting level state in the touch phase, and the pull-up nodes PU of the two shift register units GOA corresponding to the pixels in the Nth row and the (N+1)th row are both maintained in a high level state. Since the touch phase is long, the circuit structure connected to the pull-up node PU will have a certain leakage current, which will cause the voltage of the pull-up node PU to decrease after the touch phase ends. FIG. 4 is a timing diagram when the pull-up node is not compensated provided by an embodiment. In the figure, the dotted line represents the corresponding theoretical signal, the solid line represents the actual signal, PU N represents the signal of the pull-up node PU in the shift register unit GOA corresponding to the pixels in the Nth row, and PU N+1 represents the signal of the pull-up node PU in the shift register unit GOA corresponding to the pixels in the (N+1)th row. As shown in FIG. 4, if voltage compensation is not performed to the pull-up node PU, when the display scan is restored, the output capability of the gate control module 300 in the shift register unit GOA corresponding to the (N+1)th row of pixels will decrease, the gate turn-on voltage will decrease, and accordingly, the charging rate of the (N+1)th row of pixels will decrease, resulting in a horizontal stripe problem on the display screen.

In the solution of the present disclosure, as shown in FIG. 3, in the display phase Display, the waveforms of the first clock signal terminal CLKC and the second clock signal terminal CLK can be controlled to be the same.

In the touch phase Touch, the second clock signal terminal CLK is configured to output a non-conducting level to the target shift register unit, and the first clock signal terminal CLKC is configured to output a conducting level to the target shift register unit at least for part of the time. The cascade control module and the gate control module in the target shift register unit have already output a conducting level before the touch phase, and the gate control module in the shift register unit of the next stage of the target shift register unit has not output a conducting level before the touch phase. For example, as shown in FIG. 3, the target shift register unit is the shift register unit GOA corresponding to the Nth row of pixels. When the touch phase Touch is about to end, the first clock signal terminal CLKC can be controlled to repeatedly output a conducting level once to the target shift register unit, i.e., the shift register unit GOA corresponding to the Nth row of pixels, so as to recharge the pull-up node PU of the shift register unit GOA corresponding to the (N+1)th row of pixels, thereby offsetting the voltage reduction of the pull-up node PU caused by leakage during the touch period. In this way, the gate output capability of the shift register unit GOA corresponding to the (N+1)th row of pixels can be restored. At the same time, the second clock signal terminal CLK can be controlled to continuously output a non-conducting level to the shift register unit GOA corresponding to the Nth row of pixels, so the shift register unit GOA will not output a turn-on signal to the Nth row of pixels again, thereby avoiding secondary charging of the Nth row of pixels. It should be noted that secondary charging of the Nth row of pixels will cause the charging rate of the Nth row of pixels to be higher than that of other single-charged pixel rows, which will also easily cause the display horizontal stripe problem. The solution of the present disclosure controls the first clock signal terminal CLKC to repeatedly output a conducting level once to the shift register unit GOA corresponding to the Nth row of pixels, while controlling the second clock signal terminal CLK to continuously output a non-conducting level to the shift register unit GOA corresponding to the Nth row of pixels, thereby solving the above-mentioned display horizontal stripe problem caused by secondary charging. In addition, since when the pull-up node PU of the shift register unit GOA corresponding to the Nth row of pixels is charged again during the touch phase Touch, the pixels in the display area remain in a off state, which will not affect the touch detection. Therefore, the solution of the present disclosure will not occupy the effective touch detection time during the touch phase Touch, and will not affect the touch detection effect.

It can be seen that the shift register unit GOA provided in the present disclosure can effectively solve the display stripe problem caused by leakage due to circuit structure in the touch phase Touch, and benefit from the use of two different clock signal terminals to provide a turn-on signal for the cascade control module 200 and the gate control module 300, the display stripe problem caused by repeated charging can be effectively solved.

The shift register unit GOA corresponding to a row of pixels described in the present disclosure can be understood as the shift register unit GOA providing a gate driving signal to the row of pixels. For example, the shift register unit GOA corresponding to the Nth row of pixels is the shift register unit GOA that provides a gate driving signal to the Nth row of pixels.

It can be understood that the shift register unit GOA of the present disclosure can further include other functional modules such as a pull-down module, a first reset module and a control module. FIG. 5 is a schematic diagram of a structure of a shift register unit according to another embodiment of the present disclosure. As shown in FIG. 5, the shift register unit GOA may further include a first reset module 500, a pull-down module 400, a pull-down control module 600, a second reset module 700, a third reset module 800, a first coupling module 910 and a second coupling module 920, where:

The first reset module 500 is connected to the reset signal terminal Reset, the pull-up node PU and receives the first level signal LVGL. The first reset module 500 can be configured to reset the pull-up node PU by the first level signal LVGL to in response to the signal of the reset signal terminal Reset. The pull-down module 400 is connected to the pull-up node PU and the pull-down node PD and receives the first level signal LVGL. The pull-down module 400 can be configured to pull down the pull-down node PD by the first level signal LVGL in response to the signal of the pull-up node PU. The pull-down control module 600 is connected to the first power supply terminal VDD and the pull-down node PD. The pull-down control module 600 can be configured to pull up the pull-down node PD by the signal of the first power supply terminal VDD in response to the signal of the first power supply terminal VDD. The second reset module 700 is connected to the cascade signal output terminal OUT_C and the pull-down node PD and receives the first level signal LVGL. The second reset module 700 can be configured to reset the cascade signal output terminal OUT_C by the first level signal LVGL in response to the signal of the pull-down node PD. The third reset module 800 is connected to the gate signal output terminal G_Out and the pull-down node PD and receives the second level signal VGL. The third reset module 800 can be configured to reset the gate signal output terminal G_Out by the second level signal VGL in response to the signal of the pull-down node PD. The first coupling module 910 is connected to the pull-up node PU and the cascade signal output terminal OUT_C. The first coupling module 910 can be configured to couple the signal of the cascade signal output terminal OUT_C to the pull-up node PU. The second coupling module 920 is connected to the pull-up node PU and the gate signal output terminal G_Out. The second coupling module 920 can be configured to couple the signal of the gate signal output terminal G_Out to the pull-up node PU.

The first power supply terminal VDD can output a conducting level, and the pull-down control module 600 can pull up the pull-down node PD by the conducting level of the first power supply terminal VDD.

The first level signal LVGL and the second level signal VGL can both be non-conducting level signals, so that the first level signal LVGL can be configured to pull down the cascade signal output terminal OUT_C to reset it, and the second level signal VGL can be configured to pull down the gate signal output terminal G_Out to reset it.

The “pull-down” mentioned here refers to pulling the potential at the corresponding circuit node to a low level. “Pull-down” can be achieved by directional movement of the charge, so it can be specifically achieved by electronic components with corresponding functions or combinations thereof, and the present disclosure does not limit this.

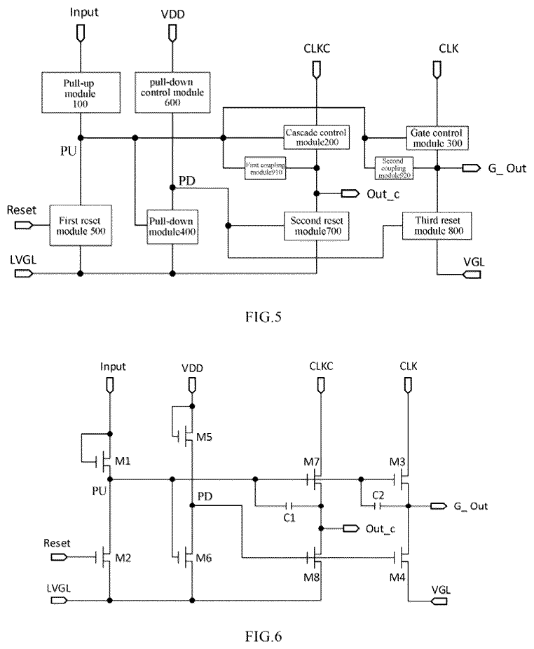

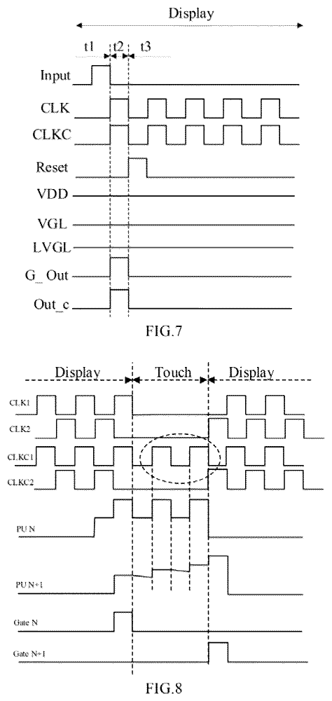

The shift register unit GOA of the present disclosure can be implemented by a transistor. For example, FIG. 6 is a circuit structure diagram of a shift register unit according to another embodiment of the present disclosure. As shown in FIG. 6, the pull-up module 100 may include a first transistor M1. A first electrode and a gate electrode of the first transistor M1 are both connected to the input terminal Input, and a second electrode is connected to the pull-up node PU. The first transistor M1 can be configured to pull up the pull-up node PU by the signal of the input terminal Input in response to the signal of the input terminal Input. The cascade control module 200 may include a seventh transistor M7. A first electrode of the seventh transistor M7 is connected to the first clock signal terminal CLKC, a second electrode is connected to the cascade signal output terminal OUT_C, and a gate electrode is connected to the pull-up node PU. The seventh transistor M7 can be configured to transmit the signal of the first clock signal terminal CLKC to the cascade signal output terminal OUT_ C in response to the signal of the pull-up node PU. The gate control module 300 may include a third transistor M3. A first electrode of the third transistor M3 is connected to the second clock signal terminal CLK, a second electrode is connected to the gate signal output terminal G_Out, and a gate electrode is connected to the pull-up node PU. The third transistor M3 can be configured to transmit the signal of the second clock signal terminal CLK to the gate signal output terminal G_Out in response to the signal of the pull-up node PU. The first reset module 500 may include a second transistor M2. A first electrode of the second transistor M2 is connected to the pull-up node PU, a second electrode receives the first level signal LVGL, and a gate electrode is connected to the reset signal terminal Reset. The second transistor M2 can be configured to reset the pull-up node PU by the first level signal LVGL in response to the signal of the reset signal terminal Reset. The pull-down module 400 may include a sixth transistor M6. A first electrode of M6 is connected to the pull-down node PD, a second electrode receives the first level signal LVGL, and a gate electrode is connected to the pull-up node PU. The sixth transistor M6 can be configured to pull down the pull-down node PD by the first level signal LVGL in response to the signal of the pull-up node PU. The pull-down control module 600 may include a fifth transistor M5. A first electrode and a gate electrode of the fifth transistor M5 are both connected to the first power supply terminal VDD, and a second electrode is connected to the pull-down node PD. The fifth transistor M5 can be configured to pull up the pull-down node PD by the signal of the first power supply terminal VDD in response to the signal of the first power supply terminal VDD. The second reset module 700 may include an eighth transistor M8. A first electrode of the eighth transistor M8 is connected to the cascade signal output terminal OUT_C, a second electrode receives the first level signal LVGL, and a gate electrode is connected to the pull-down node PD. The eighth transistor M8 can be configured to reset the cascade signal output terminal OUT_C by the first level signal LVGL in response to the signal of the pull-down node PD. The third reset module 800 may include a fourth transistor M4. A first electrode of the fourth transistor M4 is connected to the gate signal output terminal G_Out, a second electrode receives the second level signal VGL, and a gate electrode is connected to the pull-down node PD. The fourth transistor M4 can be configured to reset the gate signal output terminal G_Out by the second level signal VGL in response to the signal of the pull-down node PD. The first coupling module 910 may include a first capacitor C1. One terminal of the first capacitor C1 is connected to the pull-up node PU, and the other terminal is connected to the cascade signal output terminal OUT_C. The first capacitor C1 can couple the signal of the cascade signal output terminal OUT_C to the pull-up node PU. The second coupling module 920 may include a second capacitor C2. One terminal of the second capacitor C2 is connected to the pull-up node PU, and the other terminal is connected to the gate signal output terminal G_Out. The second capacitor C2 can couple the signal of the gate signal output terminal G_Out to the pull-up node PU.

The polarities of conducting levels of the first transistor M1 to the eighth transistor M8 mentioned above are the same. For example, they can all be N-type transistors that are turned on at a high level. Of course, in other embodiments, the first transistor M1 to the eighth transistor M8 can also be other types of transistors, which are not specifically limited here.

FIG. 7 is a timing diagram of the circuit shown in FIG. 6. As shown in FIG. 7, the driving process of the shift register unit GOA during the display phase Display may include the first stage t1 to the third stage t3:

In the first stage t1, a high-level signal is input to the input terminal Input, the first transistor M1 is turned on, and the pull-up node PU is pulled high.

In the second stage t2, the first clock signal terminal CLKC and the second clock signal terminal CLK output high-level signals, respectively controlling the seventh transistor M7 and the third transistor M3 to turn on, so that the cascade signal output terminal OUT_C and the gate signal output terminal G_Out respectively output high-level signals.

In the third stage t3, the reset signal terminal Reset outputs a high level, the second transistor M2 is turned on, and the pull-up node PU is pulled low. At the same time, the sixth transistor M6 is turned off, so that under the control of the fifth transistor M5, the pull-down node PD is pulled up to control the eighth transistor M8 and the fourth transistor M4 to be turned on. The eighth transistor M8 transmits the first level signal LVGL to the cascade signal output terminal OUT_C to reset the cascade signal output terminal OUT_C. The fourth transistor M4 transmits the second level signal VGL to the gate signal output terminal G_Out to reset the gate signal output terminal G_Out. Thereafter, the pull-up node PU maintains a low potential, and the pull-down node PD maintains a high potential until the input terminal Input acquires a high level signal again, and the above-mentioned first stage t1 to the third stage t3 are repeated.

FIG. 8 is another example timing diagram of the cascade structure shown in FIG. 2. As shown in FIG. 8, in an example embodiment, when the touch phase Touch is about to end, the first clock signal terminal CLKC can be controlled to repeatedly output the conducting level to the shift register unit GOA corresponding to the Nth row of pixels for multiple times (greater than or equal to 2 times), as shown in the dotted box in the figure. In this way, after the touch phase Touch ends, the cascade signal output terminal OUT_C of the shift register unit GOA corresponding to the Nth row of pixels can repeatedly charge the pull-up node PU N+1 of the shift register unit GOA corresponding to the (N+1)th row of pixels for multiple times, thereby playing a role in restoring the gate output capability of the shift register unit GOA corresponding to the (N+1)th row of pixels. At the same time, in the touch phase Touch, the second clock signal terminal CLK is controlled to continuously output the non-conducting level, thereby avoiding the secondary charging of the Nth row of pixels. In addition, it should be understood that the first clock signal terminal CLKC can repeatedly output the conducting level multiple times at the same time interval during the touch phase Touch, or can also repeatedly output the conducting level multiple times at different time intervals, which is not specifically limited here. Further, in some embodiments, the first clock signal terminal CLKC can also repeatedly output the conducting level multiple times in different sub-stages of the touch phase Touch, so as to charge the pull-up node PU N+1 in the shift register unit GOA corresponding to the (N+1)th row of pixels multiple times in time division, and ensure the gate output capability of the shift register unit GOA corresponding to the (N+1)th row of pixels by raising the potential of the pull-up node PU N+1 multiple times.

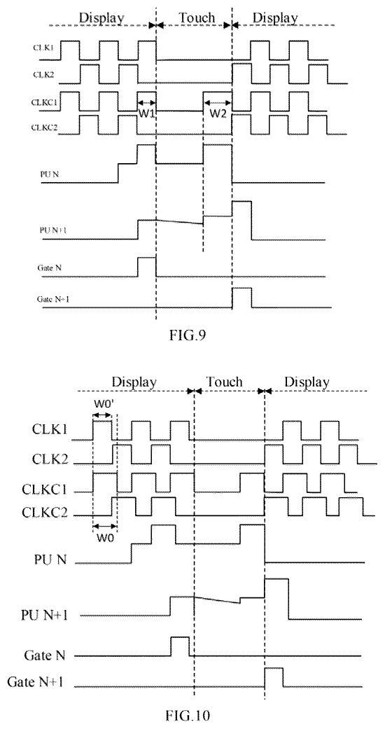

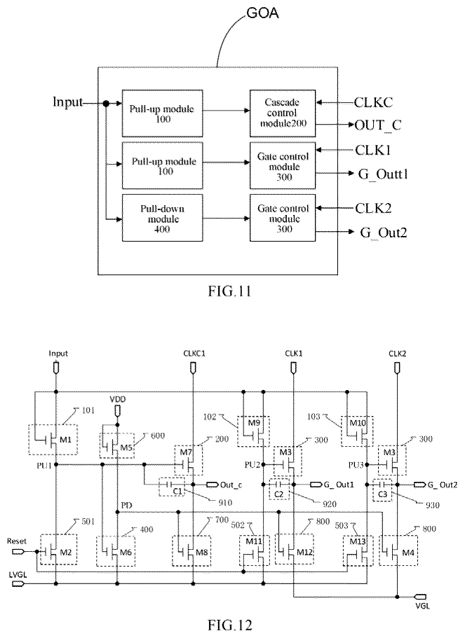

FIG. 9 is another example timing diagram of the cascade structure shown in FIG. 2. As shown in FIG. 9, in an example embodiment, the pulse width of the conducting level output by the first clock signal terminal CLKC in the touch phase Touch can be controlled to be different from the pulse width of the conducting level output in the display phase Display. For example, the pulse width W2 of the conducting level output by the first clock signal terminal CLKC in the touch phase Touch can be greater than the pulse width W1 of the conducting level output in the display phase Display. That is, the duration of the conducting level output by the first clock signal terminal CLKC in the touch phase Touch is increased, thereby increasing the charging duration of the pull-up node PU, ensuring that the pull-up node PU is fully charged. Thus, it can be avoided that the voltage of the pull-up node PU decreased due to leakage during the touch phase Touch cannot be compensated because of insufficient charging duration, so that before the touch phase Touch, the pull-up node PU has been charged and the shift register unit GOA that has not output the gate driving signal has sufficient gate output capability. For example, the pulse width of the conducting level output by the first clock signal terminal CLKC in the touch phase Touch can be greater than or equal to 1 H, where 1 H can be the effective charging time of a single row, that is, the ratio of one frame of effective display time to all pixel rows in the display panel, and one frame time is the inverse of the refresh frequency. In addition, it can be understood that in this example embodiment, the first clock signal terminal CLKC can also repeatedly output the conducting level signal shown in FIG. 9 for multiple times during the touch phase Touch. The signal output method for controlling the first clock signal terminal CLKC to repeatedly output the conducting level for multiple times during the touch phase Touch can refer to the introduction of the above embodiment and will not be described in detail here.

FIG. 10 is another example timing diagram of the cascade structure shown in FIG. 2. As shown in FIG. 10, in an example embodiment, the pulse width W0 of the conducting level output by the first clock signal terminal CLKC can be greater than the pulse width W0′ of the conducting level output by the second clock signal terminal CLK. For example, the pulse width of the conducting level output by the first clock signal terminal CLKC can be kept unchanged while the pulse width of the conducting level output by the second clock signal terminal CLK can be reduced, thereby controlling the pulse width of the cascade signal output by the shift register unit GOA to remain unchanged and controlling the pulse width of the gate driving signal output by the shift register unit GOA to decrease. In this way, the coupling effect between the gate signal line and the pixel electrode can be weakened, thereby improving the sensor horizontal stripe problem. It is worth noting that here, it means that the pulse width W0 of the conducting level output by the first clock signal terminal CLKC at any time is greater than the pulse width W0′ of the conducting level output by the second clock signal terminal CLK. That is, the pulse widths of the conducting level output in the display phase Display and in the touch phase Touch are both greater than the pulse width W0′ of the conducting level output by the second clock signal terminal CLK. For example, in one frame of data, the pulse widths of the conducting levels output by the first clock signal terminal CLKC are all W0, and the pulse widths of the conducting levels output by the second clock signal terminal CLK are all W0′, and W0>W0′. Of course, in other embodiments, the pulse width of the conducting level output by the first clock signal terminal CLKC in the touch phase Touch can be greater than the pulse width of the conducting level output by the first clock signal terminal CLKC in the display phase Display. For example, the pulse widths of the conducting levels output by the first clock signal terminal CLKC in the touch phase Touch and the display phase Display are Wt and Wd respectively, and the pulse width of the conducting level output by the second clock signal terminal CLK is W0′, and Wt>Wd>W0′. In addition, in this example embodiment, the first clock signal terminal CLKC can also repeatedly output the conducting level signal shown in FIG. 10 for multiple times in the touch phase Touch. The signal output method for controlling the first clock signal terminal CLKC to repeatedly output the conducting level for multiple times in the touch phase Touch can refer to the introduction of the above embodiment, which will not be described in detail here.

Further, in this example embodiment, in the display phase Display of the same frame data, the first clock signal terminal CLKC should output the conducting level synchronously with the second clock signal terminal CLK. As shown in FIG. 10, the structure of two first clock signal terminals CLKC and two second clock signal terminals CLK is used as an example for explanation, that is, the two first clock signal terminals CLKC and the two second clock signal terminals CLK constitute a repetitive cycle. On this basis, in the display phase Display of the same frame data, the first clock signal terminal CLKC1 should output the conducting level synchronously with the second clock signal terminal CLK1, and the first clock signal terminal CLKC2 should output the conducting level synchronously with the second clock signal terminal CLK2, so as to ensure that the shift register unit GOA normally outputs the scanning signal to drive the panel to display normally.

In the same shift register unit GOA of the present disclosure, the cascade control module 200 and the gate control module 300 can both be one or more, and the number of the gate control modules 300 is k times the number of the cascade control modules 200, and k is a positive integer greater than or equal to 1. Specifically, if k is 1, then in the same shift register unit GOA, one gate control module 300 corresponds to one cascade control module 200. At this time, the number of first clock signal terminals CLKC required by the shift register unit GOA is the same as the number of second clock signal terminals CLK. Its structure can be as shown in FIG. 1. Under this structure, one shift register unit GOA can output a gate driving signal to a row of pixels in the display area. Alternatively, if k is greater than or equal to 2, then in the same shift register unit, multiple gate control modules 300 share one cascade control module 200. This structure can reduce the number of first clock signal terminals CLKC, and one shift register unit GOA can output gate driving signals to multiple pixel rows in the display area. For example, taking k being 2, that is, two gate control modules 300 sharing one cascade control module 200 as an example, FIG. 11 is a schematic diagram of a structure of a shift register unit according to another embodiment of the present disclosure. As shown in FIG. 11, one shift register unit GOA requires one first clock signal terminal CLKC and two second clock signal terminals CLK, so that the number of the first clock signal terminals CLKC is ½ of the number of the second clock signal terminals CLK as a whole.

In an example embodiment, in the same shift register unit, when both the cascade control module 200 and the gate control module 300 are single, the cascade control module 200 and the gate control module 300 reuse the same pull-up module 100. When there are multiple gate control modules 300, the number of the pull-up modules 100 and the number of the first reset modules 500 are both the sum of the number of the cascade control modules 200 and the number of the gate control modules 300. The number of the second reset modules is the same as the number of the cascade control modules 200, and the number of the third reset modules 800 is the same as the number of the gate control modules 300.

FIG. 12 is a schematic diagram of a circuit structure for implementing the shift register unit shown in FIG. 11 according to an embodiment of the present disclosure. As shown in FIG. 12, the shift register unit GOA may include one cascade signal control module 200 and two gate control modules 300, and accordingly, include a total of two gate signal output terminals (a first gate signal output terminal G_Out1 and a second gate signal output terminal G_Out2) and one cascade signal output terminal OUT_C. In this way, one shift register unit GOA can output a cascade signal and gate driving signals to two rows of pixels. The shift register unit GOA may also include a total of three pull-up modules, namely a first pull-up module 101, a second pull-up module 102 and a third pull-up module 103. The first pull-up module 101 may include a first transistor M1, and the first pull-up module 101 may be configured to charge the first pull-up node PU1. The second pull-up module 102 may include a ninth transistor M9, and the second pull-up module 102 may be configured to charge the second pull-up node PU2. The third pull-up module 103 may include a tenth transistor M10, and the third pull-up module 103 may be configured to charge the third pull-up node PU3. Correspondingly, the shift register unit GOA may also include a total of three first reset modules 500, namely a first sub-reset module 501, a second sub-reset module 502 and a third sub-reset module 503. The first sub-reset module 501 may include a second transistor M2, the first sub-reset module 501 may be configured to reset the first pull-up node PU1. The second sub-reset module 502 may include an eleventh transistor M11, and the second sub-reset module 502 may be configured to reset the second pull-up node PU2. The third sub-reset module 503 may include a thirteenth transistor M13, and the third sub-reset module 503 may be configured to reset the third pull-up node PU3. In addition, in this example embodiment, in addition to the first coupling module 910 and the second coupling module 920, a third coupling module 930 may also be included. The first coupling module 910 connects the pull-up node PU and the cascade signal output terminal OUT_C, and the first coupling module 910 may be configured to couple the signal of the cascade signal output terminal OUT_C to the pull-up node PU. The second coupling module 920 connects the pull-up node PU and the first gate signal output terminal G_Out1, and the second coupling module 920 can be configured to couple the signal of the first gate signal output terminal G_Out1 to the pull-up node PU. The third coupling module 930 connects the pull-up node PU and the second gate signal output terminal G_Out2, and the third coupling module 930 can be configured to couple the signal of the second gate signal output terminal G_Out2 to the pull-up node PU. Similar to FIG. 6, the above-mentioned coupling modules can all be implemented by capacitors, which will not be repeated here. In addition, the shift register unit GOA shown in this example embodiment can also have other functional modules shown in FIG. 6, which will not be repeated here.

As shown in FIG. 12, in this example embodiment, the first pull-up module 101 connects the input terminal Input and the first pull-up node PU1, and the first pull-up module 101 can charge the first pull-up node PU1. The second pull-up module 102 connects the input terminal Input and the second pull-up node PU2, and the second pull-up module 102 can charge the second pull-up node PU2. The third pull-up module 103 connects the input terminal Input and the third pull-up node PU3, and the third pull-up module 103 can charge the third pull-up node PU3. In this example embodiment, after the first clock signal terminal CLKC outputs the conducting level, the voltage of the first pull-up node PU1 will be raised due to the bootstrap effect of the first sub-coupling module 901. If the second pull-up module 102 is also connected to the first pull-up node PU1 (i.e., the second pull-up node PU2 is not provided), when the second clock signal terminal CLK1 connected to the first gate control module 301 outputs the conducting level, the voltage of the first pull-up node PU1 will be raised again under the bootstrap effect of the first sub-coupling module 901, thereby causing the voltage of the first node PU1 to be too high and causing other modules to work abnormally. Therefore, in this example embodiment, by adding a second pull-up node PU2 separated from the first pull-up node PU1 and a second pull-up module 102 connected to the second pull-up node PU2, the second pull-up module 102 can be configured to charge the second pull-up node PU2, thereby effectively preventing the voltage of the first pull-up node PU1 from being too high. Similarly, the third pull-up node PU3 added and separated from the first pull-up node PU1 and the second pull-up node PU2 and the third pull-up module 103 connected to the third pull-up node PU3 can play the same role as the second pull-up node PU2 and the second pull-up module 102, which will not be described in detail here.

It should be understood that FIG. 11 and FIG. 12 are only example illustrations. In other embodiments, k can also be other positive integers greater than or equal to 2. For example, k can be 3, that is, three gate control modules 300 in the same shift register unit GOA share a cascade control module 200, etc., which will not be described in detail here.

In the present disclosure, when the same shift register unit GOA includes multiple gate control modules 300, the respective shift register units GOA can have multiple cascade modes. For example, in the same shift register unit GOA, the number of gate control modules 300 is k times the number of cascade control modules 200, and k is a positive integer greater than or equal to 1. The cascade signal output terminal OUT_C of the Nth shift register unit GOA can be connected to the input terminal Input of the shift register unit GOA of the (N+k)th stage, where N is a natural number. For example, if k=1, as shown in FIG. 2, the cascade signal output terminal OUT_C of the shift register unit GOA of the Nth stage is connected to the input terminal Input of the shift register unit GOA of the (N+1)th stage. That is, the cascade signal of the shift register unit GOA of the Nth stage is used as the input signal of the shift register unit GOA of the (N+1)th stage.

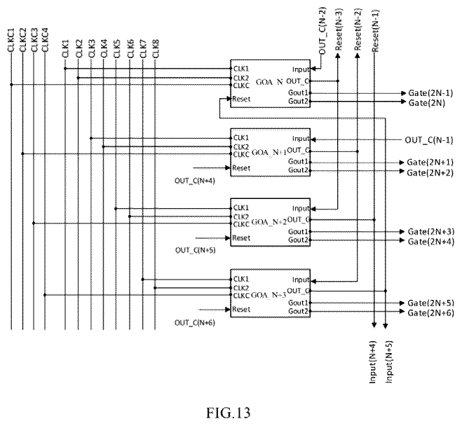

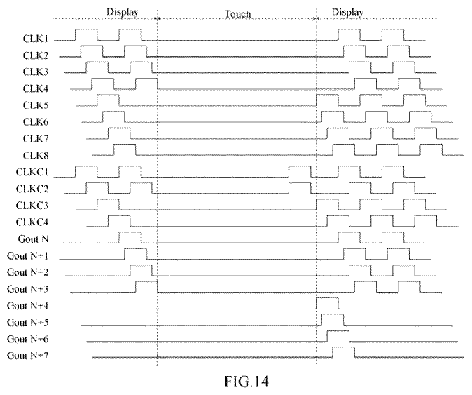

FIG. 13 is a schematic diagram of the cascade of the shift register units shown in FIG. 11. As shown in FIG. 13, k is equal to 2, and the cascade signal output terminal OUT_C of the shift register unit GOA of the Nth stage is connected to the input terminal Input of the shift register unit GOA of the (N+2)th stage, that is, the cascade signal of the shift register unit GOA of the Nth stage is used as the input signal of the shift register unit GOA of the (N+2)th stage.

In addition, in this example embodiment, the cascade signal output terminal OUT_C of the shift register unit GOA of the (N+m)-th stage is connected to the reset signal terminal Reset of the shift register unit GOA of the N-th stage, m is a positive integer greater than k, and the output signal of the first clock signal terminal CLKC connected to the shift register unit GOA of the (N+m)-th stage is different from the output signal of the first clock signal terminal CLKC connected to the shift register unit GOA of the N-th stage, where m is greater than k to ensure that the shift register unit GOA of the N-th stage is reset after the shift register unit GOA of the N-th stage fully outputs the gate driving signal, so as to avoid the situation where the shift register unit GOA of the N-th stage is reset before the shift register unit GOA of the N-th stage fully outputs the gate driving signal. On this basis, the output signal of the first clock signal terminal CLKC connected to the shift register unit GOA of the (N+m)-th stage is different from the output signal of the first clock signal terminal CLKC connected to the shift register unit GOA of the N-th stage. That is, the shift register unit GOA of the (N+m)-th stage and the shift register unit GOA of the N-th stage are connected to two different first clock signal terminals CLKC. For example, as shown in FIG. 13, m may be 3. That is, the cascade signal output terminal OUT_C of the stage shift register unit GOA of the (N+3)th stage is connected to the reset signal terminal Reset of the stage shift register unit GOA of the Nth stage.

The present disclosure also provides a touch display panel. The touch display panel may include a gate driving circuit. The gate driving circuit may include a plurality of shift register units GOA described in any of the above embodiments, and the plurality of shift register units GOA are cascaded.

In an example embodiment, the gate driving circuit may include a plurality of repeating units, a plurality of first clock signal lines, and a plurality of second clock signal lines. A repeating unit may include a plurality of cascaded shift register units GOA. The first clock signal line is configured to connect the first clock signal terminal CLKC, so as to provide a first clock signal to the corresponding shift register unit GOA through the first clock signal terminal CLKC. The second clock signal line is configured to connect the second clock signal terminal CLK, so as to provide a second clock signal to the corresponding shift register unit GOA through the second clock signal terminal CLK. The number of first clock signal lines can be a positive integer greater than or equal to 2, and the number of first clock signal lines is the same as the number of shift register units GOA contained in the repeating unit, and the number of second clock signal lines is k times the number of first clock signal lines, k is a positive integer greater than or equal to 1. Each shift register unit GOA in the same repeating unit is connected to each first clock signal line in one-to-one correspondence, and the shift register units GOA of the same stage in different repeating units are connected to the same first clock signal line. Each shift register unit GOA in the same repeating unit is connected to k second clock signal lines, and the second clock signal lines connected to the shift register units GOA of the same stage in different repeating units are the same.

For example, FIG. 13 shows a schematic diagram of a structure of a repeating unit. Referring to FIG. 13, a repeating unit may include four shift register units GOA, and accordingly, the gate driving circuit may include four first clock signal lines and eight second clock signal lines. In the first repeating unit, the shift register unit GOA of the first-stage is connected to the first clock signal line of the first one, the shift register unit GOA of the second-stage is connected to the first clock signal line of the second one, the shift register unit GOA of the third-stage is connected to the first clock signal line of the third one, and the shift register unit GOA of the fourth-stage is connected to the first clock signal line of the fourth one. In the second repeating unit, similar to the first repeating unit, each stage of the shift register unit GOA is connected to each first clock signal line in a one-to-one correspondence, and this is repeated periodically.

The present disclosure also provides a display panel driving method for driving the touch display panel described in the above embodiment of the present disclosure. The driving method may include a display phase Display and a touch phase Touch that are adjacently arranged in chronological order. That is, after a display phase Display, the touch display panel enters the touch phase Touch, and after the touch phase Touch ends, the touch display panel enters the display phase Display again, and so on. The following takes the touch display panel in any display phase Display and then entering the touch phase Touch as an example to illustrate the driving method of the present disclosure. The driving method may include the following steps:

S110, in the display phase Display, determining a target shift register unit. A cascade control module 200 and a gate control module 300 in the target shift register unit have both output a conducting level in the display phase Display, and a gate control module 300 in a shift register unit of a next stage of the target shift register unit does not output a conducting level in the display phase Display.

The driving timing in the display phase Display can be shown in FIG. 7, which is not repeated here.

The cascade control module 200 and the gate control module 300 of the target shift register unit have both output the conducting level in the display phase Display, and the gate control module 300 in the shift register unit GOA of the next stage of the target shift register unit does not output the conducting level in the display phase Display, indicating that the display panel enters the touch phase Touch after scanning the target pixel row, and the gate driving signal of the target pixel row is output by the target shift register unit.

For example, as shown in FIG. 3, the gate signal output terminal G_Out of the shift register unit GOA corresponding to the Nth row of pixels has completed outputting the gate driving signal, and its pull-up node PU is in a high level state, waiting to be reset. At the same time, the pull-up node PU of the shift register unit GOA corresponding to the (N+1)th row of pixels has just completed charging and is also in a high level state, waiting for the second clock signal terminal CLK to output a conducting level, then the shift register unit GOA corresponding to the Nth row of pixels is the target shift register unit.

For example, taking the cascade structure shown in FIG. 13 as an example, FIG. 14 is a timing diagram of the circuit shown in FIG. 13, in which a high level indicates a conducting level, and a low level indicates a non-conducting level, and the case of entering the touch phase Touch after the scanning of the (N+3)th row of pixels is completed as an example for explanation, as shown in FIG. 14. Since before entering the touch phase Touch, the pull-up nodes PU of the GOA units corresponding to the (N+4)th to (N+7)th row of pixels have been charged by the first clock signal terminals CLK1 and CLK2 respectively, the GOA units corresponding to the (N+4)th to (N+7)th row of pixels are the target shift register units.

S120, in the touch phase Touch, controlling the cascade signal output terminal OUT_C of the target shift register unit to output a conducting level by controlling the second clock signal terminal CLK to output a non-conducting level to the target shift register unit, and controlling the first clock signal terminal CLKC to output a conducting level to the target shift register unit for at least part of the time.

The first clock signal terminal CLKC outputs the conducting level to the target shift register unit for at least part of the time. That is, the first clock signal terminal CLKC can only output the conducting level for part of the time of the touch phase Touch or output the conducting level throughout the touch phase Touch. For example, as shown in FIG. 3, the first clock signal terminal CLKC outputs only one conducting level pulse to the target shift register unit before the end of the touch phase Touch. Or, as shown in FIG. 8, the first clock signal terminal CLKC can also intermittently output multiple conducting level pulses to the target shift register unit repeatedly throughout the touch phase Touch. It should be understood that the conducting level output by the first clock signal terminal CLKC in the touch phase Touch can have all the features of FIG. 9 and FIG. 10, which will not be repeated here.

In some embodiments, the first clock signal terminal CLKC can also output a conducting level with a continuous pulse width to the target shift register unit throughout the touch phase Touch, and the pulse width length of the conducting level can occupy the entire touch phase Touch, all of which belong to the protection scope of the present disclosure.

The first clock signal terminal CLKC outputs a conducting level to the target shift register unit, which can control the cascade signal output terminal OUT_C of the target shift register unit to output a conducting level. Thus, when the scan is restarted after the touch phase Touch ends, the target shift register unit can output an unattenuated, complete cascade signal to the shift register unit GOA located at the next stage of the target shift register unit, so that after the scan is restarted, the pull-up node PU of the shift register unit GOA corresponding to the pixel row waiting to be displayed is repeatedly charged, thereby effectively solving the horizontal stripe problem caused by the leakage of the pull-up node PU in the touch phase Touch in the existing GOA architecture. And by controlling the second clock signal terminal CLK to output a non-conducting level, the pixel row can be avoided from being recharged. In the touch phase Touch, it can thus avoid the horizontal stripe problem caused by the repeated charging of the pull-up node of the target shift register unit in the existing solution, which causes the pixel row corresponding to the target shift register unit to be recharged.

For example, as shown in FIG. 14, the waveforms of the four first clock signal terminals CLKC1 to CLKC4 correspond to the same waveforms of the second clock signal terminals CLK1, CLK3, CLK5, and CLK7 in the display phase Display. Before entering the touch phase Touch, the pull-up nodes PU of the GOA units corresponding to the pixels in the (N+4)th to (N+7)th rows have been charged by the first clock signal terminals CLK1 and CLK2, respectively. Therefore, when the touch phase Touch is about to end, by controlling the first clock signal terminal CLKC1 and the first clock signal terminal CLKC2 to generate high-level pulses, the pull-up nodes PU of the GOA units corresponding to the pixels in the (N+4)th to (N+7)th rows that are about to resume display scanning can be repeatedly charged, thereby compensating for the voltage drop of the GOA units corresponding to the pixels in the (N+4)th to (N+7)th rows caused by leakage of the pull-up nodes PU in the touch phase Touch. At the same time, the signals at the second clock signal terminals CLK are controlled to maintain a low level to avoid recharging the pixels in the Nth to (N+3)th rows.

After completing the touch phase Touch, the touch display panel can enter the display phase Display again, and can be driven to display according to the driving method as shown in step S110, and so on, until a frame of data is displayed, and the next frame of data is displayed after the Blank phase.

After considering the specification and practicing the present disclosure herein, it will be easy for those skilled in the art to think of other embodiments of the present disclosure. The present disclosure is intended to cover any variation, use or adaptive change of the present disclosure, which follows the general principles of the present disclosure and includes common knowledge or conventional technical means in the field of the present technology that are not disclosed in the present disclosure. The specification and embodiments are only to be regarded as examples, and the true scope and spirit of the present disclosure are indicated by the attached claims.

1. A shift register unit, comprising:
a pull-up module connected to an input terminal and a pull-up node, wherein the pull-up module is configured to pull up the pull-up node by a signal of the input terminal in response to the signal of the input terminal;
a cascade control module connected to a first clock signal terminal, the pull-up node and a cascade signal output terminal, wherein the cascade control module is configured to transmit a signal of the first clock signal terminal to the cascade signal output terminal in response to a signal of the pull-up node; and
a gate control module connected to the pull-up node, a second clock signal terminal and a gate signal output terminal, wherein the gate control module is configured to transmit a signal of the second clock signal terminal to the gate signal output terminal in response to the signal of the pull-up node.

2. The shift register unit according to claim 1, wherein the cascade control module and the gate control module are both one or more, and a number of the gate control modules is k times a number of the cascade control modules, and k is a positive integer greater than or equal to 1.

3.-8. (canceled)

9. The display panel according to claim 1, wherein a pulse width of a conducting level output by the first clock signal terminal is greater than or equal to a pulse width of a conducting level output by the second clock signal terminal.

10. The shift register unit according to claim 1, wherein the shift register unit further comprises:
a first reset module connected to a reset signal terminal, the pull-up node and receiving a first level signal, wherein the first reset module is configured to reset the pull-up node by the first level signal in response to a signal of the reset signal terminal;
a pull-down module connected to the pull-up node and a pull-down node and receiving the first level signal, wherein the pull-down module is configured to pull down the pull-down node by the first level signal in response to the signal of the pull-up node;
a pull-down control module connected to a first power supply terminal and the pull-down node, wherein the pull-down control module is configured to pull up the pull-down node by a signal of the first power supply terminal in response to the signal of the first power supply terminal;
a second reset module connected to the cascade signal output terminal, the pull-down node and receiving the first level signal, wherein the second reset module is configured to reset the cascade signal output terminal by the first level signal in response to a signal of the pull-down node;
a third reset module connected to the gate signal output terminal, the pull-down node and receiving a second level signal, wherein the third reset module is configured to reset the gate signal output terminal by the second level signal in response to the signal of the pull-down node;
a first coupling module connected to the pull-up node and the cascade signal output terminal, wherein the first coupling module is configured to couple a signal of the cascade signal output terminal to the pull-up node; and
a second coupling module connected to the pull-up node and the gate signal output terminal, wherein the second coupling module is configured to couple a signal of the gate signal output terminal to the pull-up node.

11. The shift register unit according to claim 10, wherein when the cascade control module and the gate control module are both single, the cascade control module and the gate control module share a same pull-up module;
when there are multiple gate control modules, a number of the pull-up modules and a number of the first reset modules are both a sum of a number of the cascade control modules and a number of the gate control modules, a number of the second reset modules is same as the number of the cascade control modules, and a number of the third reset modules is same as the number of the gate control modules.

12. The shift register unit according to claim 10, wherein the pull-up module comprises:
a first transistor, wherein a first electrode and a gate electrode of the first transistor are both connected to the input terminal, a second electrode of the first transistor is connected to the pull-up node, the first transistor is configured to pull up the pull-up node by the signal of the input terminal in response to the signal of the input terminal;
the cascade control module comprises:
a seventh transistor, wherein a first electrode of the seventh transistor is connected to the first clock signal terminal, a second electrode of the seventh transistor is connected to the cascade signal output terminal, a gate electrode of the seventh transistor is connected to the pull-up node, the seventh transistor is configured to transmit the signal of the first clock signal terminal to the cascade signal output terminal in response to the signal of the pull-up node;
the gate control module comprises:
a third transistor, wherein a first electrode of the third transistor is connected to the second clock signal terminal, a second electrode of the third transistor is connected to the gate signal output terminal, a gate electrode of the third transistor is connected to the pull-up node, and the third transistor is configured to transmit the signal of the second clock signal terminal to the gate signal output terminal in response to the signal of the pull-up node;
the first reset module comprises:
a second transistor, wherein a first electrode of the second transistor is connected to the pull-up node, a second electrode of the second transistor receives the first level signal, a gate of the second transistor is connected to the reset signal terminal, and the second transistor is configured to reset the pull-up node by the first level signal in response to the signal of the reset signal terminal;
the pull-down module comprises:
a sixth transistor, a first electrode of the sixth transistor is connected to the pull-down node, a second electrode of the sixth transistor receives the first level signal, a gate electrode of the sixth transistor is connected to the pull-up node, and the sixth transistor is configured to pull down the pull-down node by the first level signal in response to the signal of the pull-up node;
the pull-down control module comprises:
a fifth transistor, wherein a first electrode and a gate electrode of the fifth transistor are both connected to the first power supply terminal, a second electrode of the fifth transistor is connected to the pull-down node, the fifth transistor is configured to pull up the pull-down node by the signal of the first power supply terminal in response to the signal of the first power supply terminal;
the second reset module comprises:
an eighth transistor, wherein a first electrode of the eighth transistor is connected to the cascade signal output terminal, a second electrode of the eighth transistor receives the first level signal, a gate electrode of the eighth transistor is connected to the pull-down node, and the eighth transistor is configured to reset the cascade signal output terminal by the first level signal in response to the signal of the pull-down node;
the third reset module comprises:
a fourth transistor, wherein a first electrode of the fourth transistor is connected to the gate signal output terminal, a second electrode of the fourth transistor receives the second level signal, a gate electrode of the fourth transistor is connected to the pull-down node, and the fourth transistor is configured to reset the gate signal output terminal by the second level signal in response to the signal of the pull-down node;
the first coupling module comprises:
a first capacitor, wherein one terminal of the first capacitor is connected to the pull-up node and another terminal is connected to the cascade signal output terminal, and the first capacitor is configured to couple the signal of the cascade signal output terminal to the pull-up node;
the second coupling module comprises:
a second capacitor, wherein one terminal of the second capacitor is connected to the pull-up node and another terminal is connected to the gate signal output terminal, and the first capacitor is configured to couple the signal of the gate signal output terminal to the pull-up node.

13. The shift register unit according to claim 12, wherein polarities of the conducting levels of the first transistor to the eighth transistor are same.

14. A touch display panel, comprising a gate driving circuit, wherein the gate driving circuit comprises a plurality of shift register units according to claim 1, and the plurality of shift register units are cascaded.

15. The touch display panel according to claim 14, wherein the gate driving circuit comprises:
a plurality of repeating units, wherein the repeating unit comprises a plurality of cascaded shift register units;
at least two first clock signal lines, wherein the first clock signal line is configured to connect the first clock signal terminal;
at least two second clock signal lines, wherein the second clock signal line is configured to connect the second clock signal terminal;
wherein, a number of the first clock signal lines is same as a number of the shift register units contained in the repeating unit, and a number of the second clock signal lines is k times the number of the first clock signal lines, wherein k is a positive integer greater than or equal to 1;
shift register units in a same repeating unit are connected to the first clock signal lines in one-to-one correspondence, and shift register units of a same stage in different repeating units are connected to a same first clock signal line; and
each shift register unit in the same repeating unit is connected to k second clock signal lines, and shift register units of the same stage in different repeating units are connected to same second clock signal lines.

16. A display panel driving method, for driving the touch display panel according to claim 14, wherein the method comprises: arranging a display phase and a touch phase adjacent to each other in time sequence,
in the display phase, determining a target shift register unit, a cascade control module and a gate control module in the target shift register unit both have output a conducting level in the display phase, and a gate control module in a shift register unit of a next stage of the target shift register unit does not output a conducting level in the display phase;
in the touch phase, controlling a cascade signal output terminal of the target shift register unit to output the conducting level by controlling the second clock signal terminal to output a non-conducting level to the target shift register unit, and controlling the first clock signal terminal to output the conducting level to the target shift register unit for at least part of time.

17. The driving method according to claim 16, wherein in the touch phase, a number of conducting levels output by the first clock signal terminal to the target shift register unit is one or more.

18. The touch display panel according to claim 14, wherein a cascade signal output terminal of a shift register unit of a Nth stage is connected to an input terminal of a shift register unit of a (N+k)th stage, and N is a natural number.

19. The touch display panel according to claim 18, wherein when k is 1, a cascade signal output terminal of a shift register unit of a (N+1)th stage is connected to a reset signal terminal of a shift register unit of a Nth stage; and
when k is greater than or equal to 2, a cascade signal output terminal of a shift register unit of a (N+m)th stage is connected to a reset signal terminal of a shift register unit of a Nth stage, N is a natural number, m is a positive integer greater than k, and an output signal of a first clock signal terminal connected to the shift register unit of the (N+m)th stage is different from an output signal of a first clock signal terminal connected to the shift register unit of the Nth stage.

20. The touch display panel according to claim 14, wherein the shift register unit is configured to output a gate driving signal to drive the touch display panel, and the touch display panel alternately operates in a display phase and a touch phase;
when the touch display panel operates in the touch phase, the second clock signal terminal is configured to output a non-conducting level to a target shift register unit, and the first clock signal terminal is configured to output a conducting level to the target shift register unit for at least part of time, wherein a cascade control module and a gate control module in the target shift register unit have both output a conducting level before the touch phase, and a gate control module in a shift register unit of a next stage of the target shift register unit does not output a conducting level before the touch phase.

21. The touch display panel according to claim 20, wherein a pulse width of the conducting level output by the first clock signal terminal in the touch phase is greater than or equal to a pulse width of the conducting level output by the first clock signal terminal in the display phase.

22. The touch display panel according to claim 21, wherein the pulse width of the conducting level output by the first clock signal terminal in the touch phase is greater than or equal to effective charging time of a row of pixels.

23. The touch display panel according to claim 20, wherein, in the touch phase, a number of the conducting levels output by the first clock signal terminal to the target shift register unit is one or more.
